(19) United States
(12) Patent Application Publication
(10) Pub. No.: US 2012/0175746 A1
(43) Pub. Date: Jul. 12, 2012

(54) Selective Deposition in the Fabrication of Electronic Substrates

(76) Inventors: YounSang Kim, Irvine, CA (US); Robert William Palmer, Yorba Linda, CA (US)

(21) Appl. No.: 13/351,594

(22) Filed: Jan. 17, 2012

Related U.S. Application Data
(63) Continuation of application No. 13/004,924, filed on Jan. 12, 2011, now abandoned.

(51) Int. Cl. H01L 25/07

(52) U.S. Cl. 257/622; 257/E25.018

(57) ABSTRACT

A semiconductor substrate is coated with a single layer of different materials selected from adhesives, coatings, and encapsulants.

### CROSS-REFERENCE TO RELATED APPLICATION

This application is a continuation of U.S. patent application Ser. No. 13/004,924 filed Jan. 12, 2011, the contents of which are incorporated herein by reference.

### BACKGROUND OF THE INVENTION

This invention relates to a method of selectively depositing more than one type of material used in the preparation of electronic devices, and in particular to semiconductor wafers and individual semiconductor dies, to a surface of the device, wafer or die.

In the fabrication of electronic devices, various adhesives, encapsulants, and protective coatings are applied by printing to semiconductor wafers and individual semiconductor dies. The printing processes in current use dispose one type of material onto the surface of the wafer or die. However, the functionality of that material may not always give optimum performance over the totality of the surface coated because different areas of the surface are involved in different functions.

The instant invention is a solution to this by providing for the selective depositing of materials over the surface of a semiconductor wafer or individual semiconductor die.

### SUMMARY OF THE INVENTION

This invention is a method for depositing two or more fabrication materials onto the surface of an electronic substrate comprising (a) providing the substrate; (b) providing two or more materials to be deposited onto the surface of the substrate; (c) providing two or more movable means for depositing those materials, each means containing a reservoir of a material to be deposited onto the surface of the substrate; (d) depositing the materials onto selected areas of the electronic substrate according to a predetermined pattern consistent with the functionality of that part of the substrate. In one embodiment the substrate is a semiconductor wafer or die, or a circuit board. In a preferred embodiment, the materials are selected from the group consisting of adhesives, encapsulants, and coatings, for example, solder paste, underfill, coatings, and sealants. In a preferred embodiment, depositing is accomplished by printing.

### BRIEF DESCRIPTION OF THE FIGURES

FIG. 1 is a cross sectional depiction of stacked semiconductor wafers with an adhesive disposed between the wafers showing the current state of the art.

FIG. 2 is a cross sectional depiction of stacked semiconductor wafers with more than one adhesive disposed between the wafers showing the instant invention.

FIG. 3 depicts a topside view of a wafer with individual dies before and after dicing showing the use of two different adhesives.

FIG. 4 is a depiction of wafer printing and coating, showing how deposition means work in the disposition of two different materials. The dicing lines and circuitry are not shown; the horizontal and vertical lines represent printed adhesive, encapsulant, or coating.

FIG. 5 shows the disposition of two different materials for wafer backside coatings.

FIG. 6 depicts the disposition of three different materials for through-vias in silicon dies.

FIG. 7 depicts selective applications for wire encapsulation .

FIG. 8 depicts the use of transparent material and high flow adhesive for image sensors and encapsulants.

FIG. 9 shows the use of the selective deposition method for fluxing agents and underfill encapsulants.

### DETAILED DESCRIPTION OF THE INVENTION

In the fabrication of electronic devices, and in particular, in the fabrication of semiconductor wafers and dies, various types of adhesives, encapsulants, and coatings are used to impart functionality and to provide protection. These materials are applied by various means, in many instances by some form of printing, and in many cases, to the semiconductor wafer before it is singulated into individual dies.

The surfaces of the devices or semiconductors (also called “substrates” herein) are patterned with elements of circuitry. These circuitry elements and the surrounding areas form patterns and relate to specific functions in the operation of the semiconductor or device. In current practice, typically only one type of material is applied per layer (of adhesive, encapsulant, or coating) to impart functionality or protection.

In some situations, it would be preferable to be able to deposit more than one type of material per layer over the surface, thereby enhancing optimum performance over the totality of the surface, inasmuch as different areas of the surface are involved in different functions and have different performance requirements.

This is accomplished through the instant method of selectively printing, in which two or more printing heads, each containing a different material (such as, adhesive, coating, or encapsulant) used in the fabrication of the device or semiconductor to be printed, are used to deposit the material onto the surface of the device or semiconductor in a predetermined pattern consistent with the functionality of that part of the surface of the substrate. In one embodiment, the means of deposition is printing, and the printing means can be any that are effective for accomplishing the deposition of the particular material. Ink jet printing is one method that can be used to deposit material.

Applications in which the instant invention can be used are referenced in the Figures.

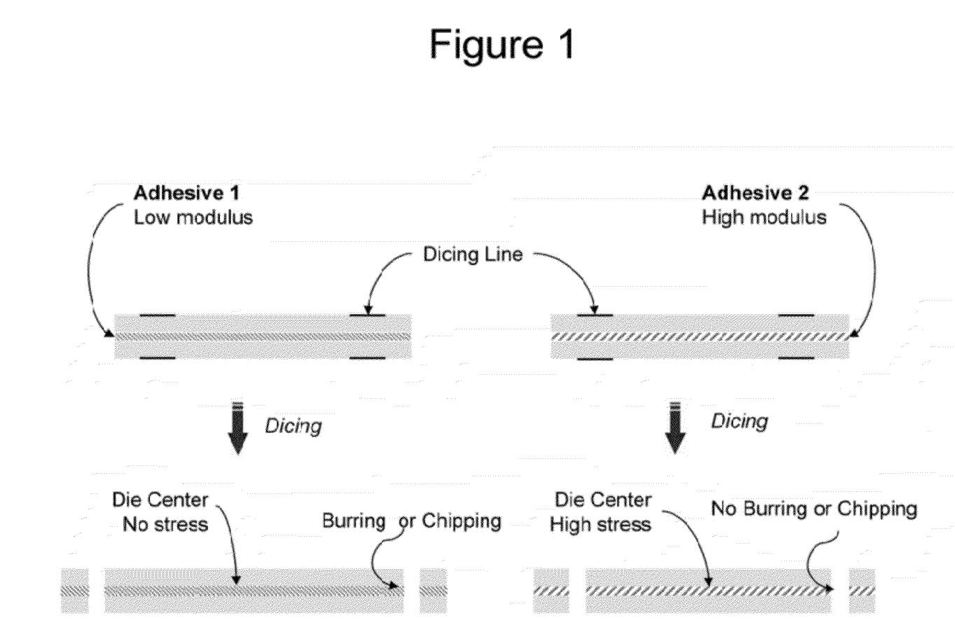

In the industry drive toward faster production, the stacking of semiconductor wafers for simultaneous dicing of all the wafers in the stack is becoming standard operation. An adhesive is used to hold the wafers aligned. If the adhesive is a low modulus adhesive, the centers of the dies diced from the wafer have lower stress and greater reliability; however, the edges of the dies relating to the dicing lines on the wafer suffer burring or chipping. If the adhesive is a high modulus, more brittle adhesive, the edges of the dies do not become burred or chipped; however, the center of the die is easily stressed and reliability decreases. This is shown in FIG. 1.

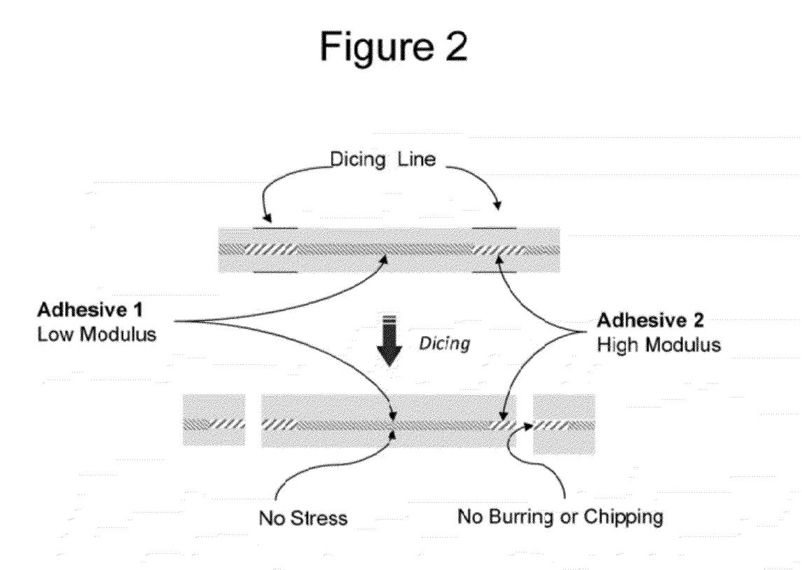

FIG. 2 depicts the solution to this problem and shows two stacked semiconductor wafers adhered together with a single layer of adhesive in which the adhesive along the dicing line is a high modulus adhesive, and the adhesive in the remaining area off the dicing line is a low modulus adhesive.

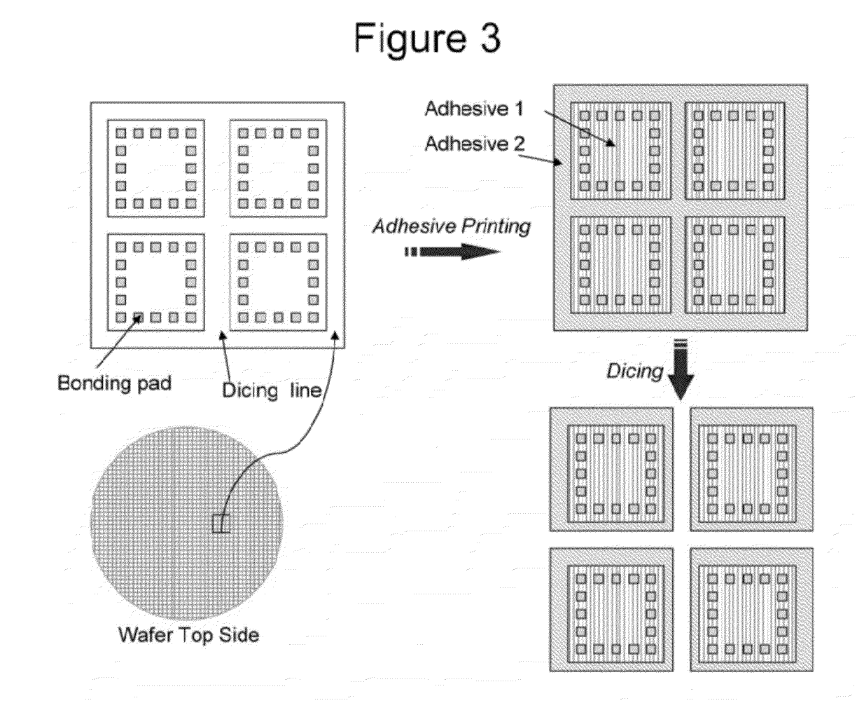

FIG. 3 is the topside view of the wafer showing bonding pads and dicing lines.

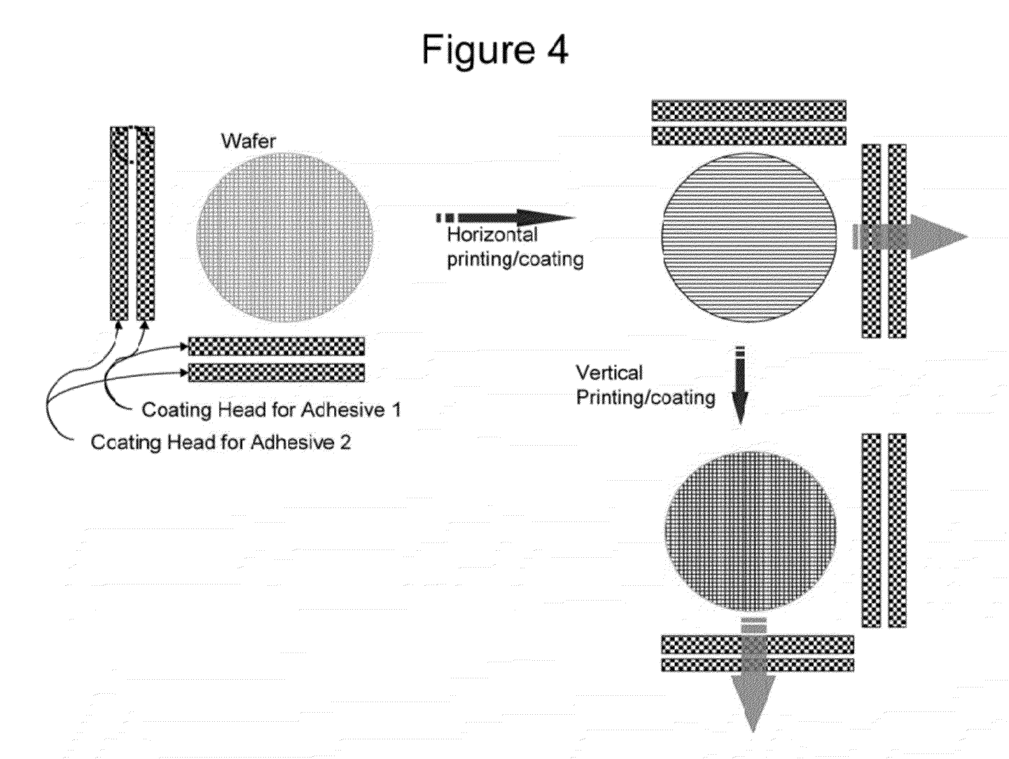

FIG. 4 is a depiction of how multiple sets of deposition means, in this figure two sets, each moving 90 degrees relative to the other, can be used to deposit different adhesives in one layer. Each deposition means will deposit one of the adhesives, encapsulants or coatings. The deposition means can be, for example, ink jet nozzles or blades.

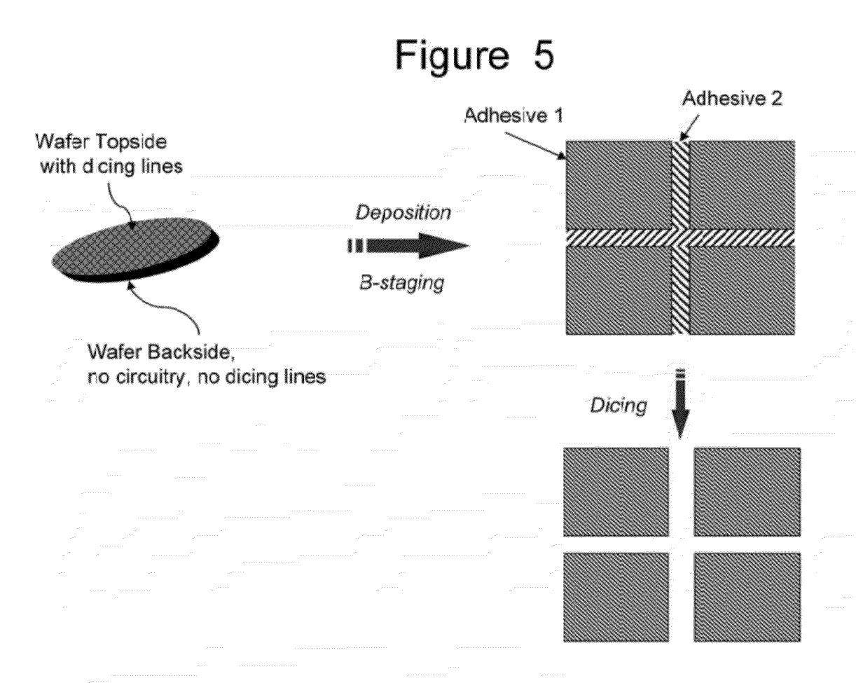

The selective printing method may also be used to deposit any of the various protective materials used in the industry for wafer backside coatings. FIG. 5 is a depiction of the printing of a high modulus adhesive and a low modulus adhesive on the backside of a wafer, and the subsequent dicing of the wafer into individual dies.

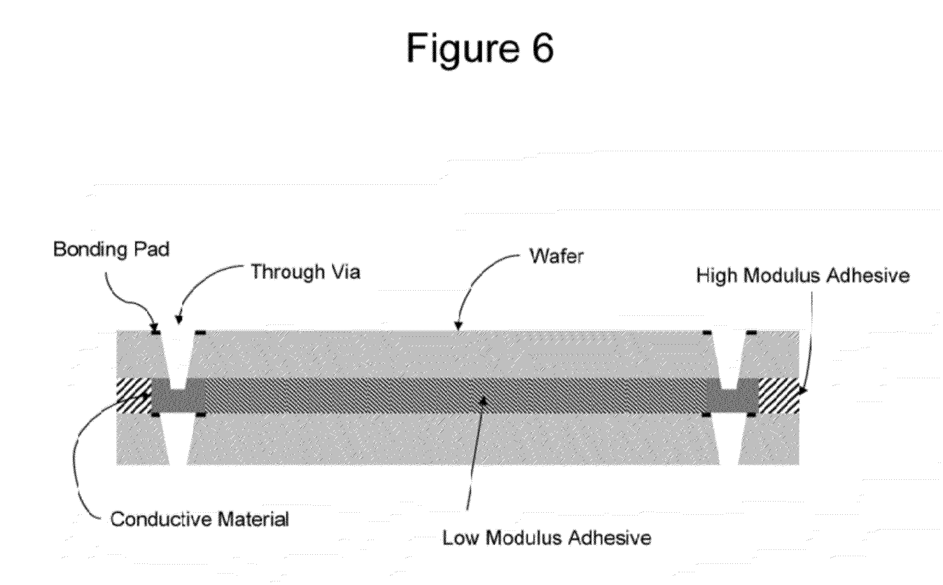

Through-vias are pathways through a semiconductor die to accommodate the positioning of conductive leads from the bondpad on one surface of the die through to the surface of another die. In one embodiment in which dies are stacked, the via on one die leads from one surface to the other surface and to a conductive material on that other surface, and from there to another via in another die. This is shown in FIG. 6. The selective deposition method of this invention will permit the deposition of a high modulus adhesive along the dicing lines of the semi-conductor wafer from which the dies will be diced, the deposition of conductive material at the via openings for the dies, and the deposition of low modulus adhesive in the center of the die. These depositions typically will take place at the wafer level, with respect to patterns for singulating (dicing) the individual dies.

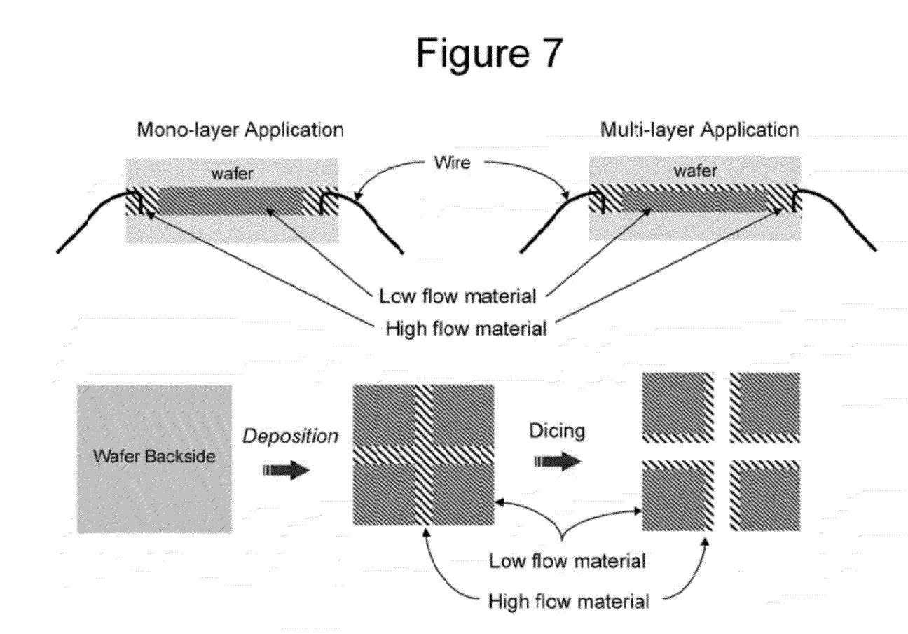

FIG. 7 is a depiction of mono-layer and multi-layer selective depositions for wire encapsulation. This type of selective deposition can be used in applications to protect wire bonding in die stacking arrangements. In die stacks, a high flow, high modulus adhesive can be applied to the wire bonding area, and a low flow, low modulus adhesive can be applied to the remainder of the semiconductor die for conventional bond line thickness and stress release.

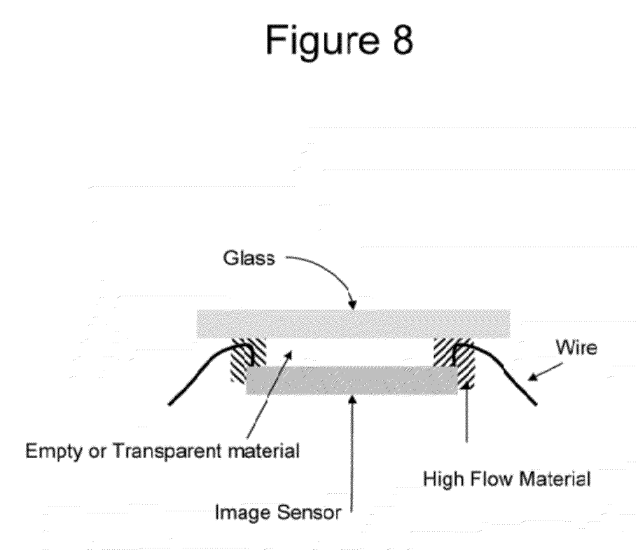

For image sensors, transparent filler materials are needed to protect and cover the image sensor and high flow adhesives are used to cover bonding wires. FIG. 8 is a depiction of an image sensor illustrating the placement of the transparent material and wire adhesive in one embodiment, which can be achieved by selective deposition in one layer.

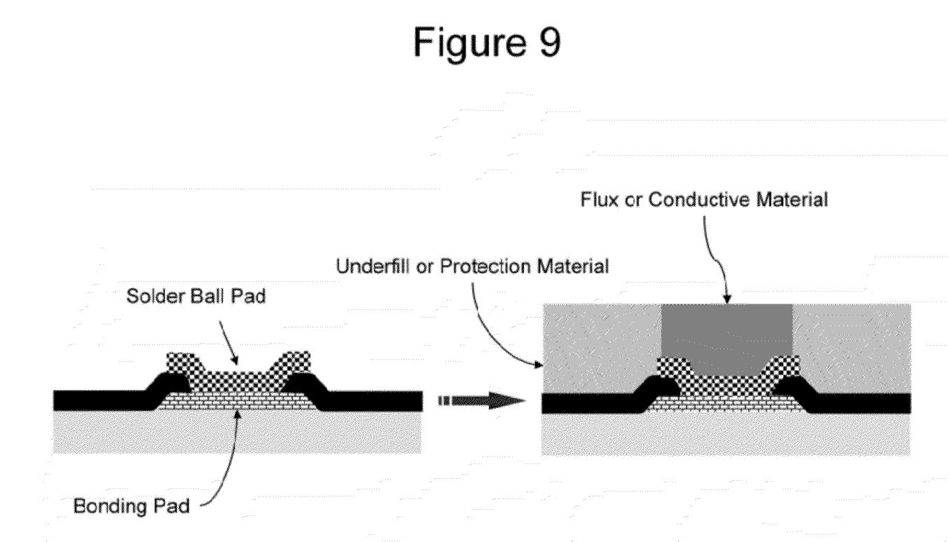

Selective deposition can also be used for depositing fluxing agents and underfills for flip-chip devices. Fluxing agents can be deposited onto the solder ball pads on flip-chip devices, and underfill encapsulant can be deposited on the area surrounding the solder ball pads. This is shown in FIG. 9.

It is also possible to use selective deposition, particularly when jet printing is the means of deposition, to apply multiple layers of adhesive or coating in very thin thicknesses to accommodate tight tolerances.

1. A semiconductor substrate coated with a single layer of different materials selected from adhesives, coatings, and encapsulants.

2. The semiconductor substrate according to claim 1 in which the substrate comprises stacked semiconductor wafers with dicing lines, the wafers adhered together with a single layer of adhesive, in which the adhesive along the dicing lines is a high modulus adhesive, and the adhesive off the dicing lines is a low modulus adhesive.

3. The semiconductor substrate according to claim 1 in which the substrate comprises a semiconductor wafer with via openings and a die pattern formed with dicing lines, the semiconductor wafer coated with a high modulus adhesive along the dicing lines, a conductive material at the via openings, and a low modulus adhesive in the center of the die pattern formed by the dicing lines.

4. The semiconductor substrate according to claim 1 in which the substrate comprises a stack of semiconductor dies having wire bonds, in which a high flow, high modulus adhesive is applied to the wire bonds, and a low flow, low modulus adhesive is applied to the remainder of the semiconductor dies.

5. The semiconductor substrate according to claim 1 in which the substrate comprises an image sensor coated with a transparent filler material and wire bonds covered with a high flow adhesive.

6. The semiconductor substrate according to claim 1 in which the substrate comprises a flip-chip device containing solder ball pads in which a fluxing agent is coated onto the solder ball pads and an underfill encapsulant is coated on the area surrounding the solder ball pads.
